(19) United States
(12) Patent Application Publication
(10) Pub. No.: US 2026/0123047 A1
(43) Pub. Date: Apr. 30, 2026

(54) SEMICONDUCTOR INTEGRATED CIRCUIT DEVICE

(71) Applicant: Socionext Inc., Kanagawa (JP)

(72) Inventor: Kohei KOMADA, Yokohama-shi (JP)

(21) Appl. No.: 19/416,197

(22) Filed: Dec. 11, 2025

Related U.S. Application Data
(63) Continuation of application No. PCT/JP2023/025184, filed on Jul. 6, 2023.

(51) Int. Cl. H10D 84/90

(52) U.S. Cl. CPC H10D 84/981

(57) ABSTRACT

A power tap row including power taps is provided adjacently to a plurality of cell rows. A first cell includes: transistors overlapping each other in planar view; a first power line formed in a first interconnect layer, and a second power line formed in a second interconnect layer. Each power tap includes: a third power line formed in the first interconnect layer; a fourth power line formed in the second interconnect layer; and a connection structure for connecting the third and fourth power lines. The size of the first cell in the X direction is larger than the wiring pitch of fifth power lines formed in a third interconnect layer.

### CROSS-REFERENCE TO RELATED APPLICATIONS

This is a continuation of International Application No. PCT/JP2023/025184 filed on Jul. 6, 2023. The entire disclosure of this application is incorporated by reference herein.

### BACKGROUND

The present disclosure relates to a layout structure of a semiconductor integrated circuit device.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, whereby an LSI chip is designed.

For higher integration of a semiconductor integrated circuit device, there is available a complementary field effect transistor (CFET) technique in which transistors are stacked one upon another in the direction normal to the substrate. The direction normal to the substrate is herein called the depth direction. Also, there is proposed a semiconductor integrated circuit device in which an interconnect layer is provided on the back side of transistors and power lines and signal lines are placed in this backside interconnect layer.

US Patent Application Publication No. 2023/0069137 (FIG. 4B) discloses a configuration of a semiconductor integrated circuit device using the CFET technique, in which an interconnect layer is provided on the back side of transistors. In this configuration, power tap cells are provided for connecting power lines (VSS) placed in the backside interconnect layer and power lines placed in an upper-side interconnect layer.

However, in the configuration of the cited patent document, in the power tap cells, since vias are provided for connecting the upper-side interconnect layer and the backside interconnect layer, no transistors can be placed. That is, transistors can only be placed between the power tap cells.

On the other hand, as voltages are becoming lower and lower in semiconductor integrated circuit devices, it has become necessary to place power lines densely for avoiding problems such as performance degradation and malfunction due to a power supply voltage drop. For this reason, in the configuration of the cited patent document, it becomes necessary to reduce the spacing of arrangement of the power tap cells. Since this will also reduce the maximum width of a cell that can be placed between the power tap cells, the degree of freedom of placement of cells large in circuit scale such as a flipflop will decrease. This causes a problem of making the design of a semiconductor integrated circuit device difficult and degrading the performance of the device.

An objective of the present disclosure is presenting a layout structure high in the degree of freedom of placement of cells large in circuit scale in a semiconductor integrated circuit device having power taps.

### SUMMARY

According to the first mode of the disclosure, a semiconductor integrated circuit device includes: a plurality of cell rows each including a plurality of standard cells arranged in a first direction, the cell rows being arranged adjacently in a second direction perpendicular to the first direction; and a power tap row including a plurality of power taps arranged in the first direction, the power tap row being adjacent to the plurality of cell rows in the second direction, wherein the plurality of cell rows include a first standard cell, the first standard cell includes a first transistor of a first conductivity type, a second transistor of a second conductivity type formed above the first transistor in a depth direction and overlapping the first transistor in planar view, a first power line formed in a first interconnect layer located on a back side of the first and second transistors, extending in the first direction, and supplying a first power supply voltage to the first transistor, and a second power line formed in a second interconnect layer located on an upper side of the first and second transistors, extending in the first direction, and supplying a second power supply voltage to the second transistor, the power tap includes a third power line formed in the first interconnect layer, extending in the first direction, and supplying the second power supply voltage, a fourth power line formed in the second interconnect layer, extending in the first direction, overlapping the third power line in planar view, and supplying the second power supply voltage, and a connection structure for connecting the third power line and the fourth power line, the semiconductor integrated circuit device further includes a plurality of fifth power lines formed in a third interconnect layer located below the first interconnect layer, extending in the second direction, and supplying the second power supply voltage, the plurality of fifth power lines are arranged at a first pitch in the first direction, and the size of the first standard cell in the first direction is larger than the first pitch.

According to the above mode, in the semiconductor integrated circuit device, a power tap row including a plurality of power taps is provided adjacently to a plurality of cell rows each including standard cells arranged in the first direction. A first standard cell in the cell rows includes: first and second transistors overlapping each other in planar view; a first power line supplying a first power supply voltage formed in a first interconnect layer located on the back side; and a second power line supplying a second power supply voltage formed in a second interconnect layer located on the upper side. Each power tap includes: a third power line supplying the second power supply voltage formed in the first interconnect layer; a fourth power line supplying the second power supply voltage formed in the second interconnect layer; and a connection structure for connecting the third and fourth power lines. Having this configuration, since the power tap row is provided separately from the plurality of cell rows, it is unnecessary to place a power tap cell in the plurality of cell rows. The semiconductor integrated circuit device further includes a plurality of fifth power lines supplying the second power supply voltage formed in a third interconnect layer located below the first interconnect layer. Also, the size of the first standard cell in the first direction is larger than a first pitch at which the plurality of fifth power lines are arranged. That is, since the degree of freedom of placement of cells large in circuit scale enhances in the plurality of cell rows, the design of the semiconductor integrated circuit device becomes easy, whereby the performance can be improved.

According to the present disclosure, it is possible to implement a layout structure high in the degree of freedom of placement of cells large in circuit scale in a semiconductor integrated circuit device having power taps.

### BRIEF DESCRIPTION OF THE DRAWINGS

FIGS. 1A-1B are plan views showing a layout example of a circuit block in a semiconductor integrated circuit device according to an embodiment, where FIG. 1A shows an M0 layer and an M1 layer and FIG. 1B shows a BM0 layer and a BM1 layer.

FIG. 2A is a plan view showing a layout example of the circuit block in the semiconductor integrated circuit device according to the embodiment, showing M1 to M3 layers.

FIG. 2B is a plan view showing a layout example of the circuit block in the semiconductor integrated circuit device according to the embodiment, showing M3 to M5 layers.

FIG. 3A is a plan view showing a layout example of the circuit block in the semiconductor integrated circuit device according to the embodiment, showing BM1 to BM3 layers.

FIG. 3B is a plan view showing a layout example of the circuit block in the semiconductor integrated circuit device according to the embodiment, showing BM3 to BM5 layers.

FIG. 4 shows another configuration example of the semiconductor integrated circuit device according to the embodiment.

FIGS. 5A-5B are plan views showing an example of the layout structure of an inverter cell, where FIG. 5A shows a lower part and FIG. 5B shows an upper part.

FIGS. 6A and 6B are cross-sectional views of the layout structure of the inverter cell.

FIGS. 7A-7B are plan views showing an example of the layout structure of a 2-input NAND circuit cell, where FIG. 7A shows a lower part and FIG. 7B shows an upper part.

FIGS. 8A-8B are plan views showing an example of the layout structure of a 2-input NOR circuit cell, where FIG. 8A shows a lower part and FIG. 8B shows an upper part.

FIGS. 9A-9C are views showing an example of the layout structure of a power tap cell, where FIGS. 9A and 9B are plan views and FIG. 9C is a cross-sectional view.

FIG. 10 is a cross-sectional view showing a configuration of the neighborhood of the power tap cell.

### DETAILED DESCRIPTION

An embodiment of the present disclosure will be described hereinafter with reference to the accompanying drawings. In the following embodiment, it is assumed that the semiconductor integrated circuit device includes a plurality of standard cells (hereinafter simply called cells as appropriate), and at least some of the standard cells include nanosheet field effect transistors (FETs). Note however that, in the present disclosure, the transistors included in the standard cells are not limited to nanosheet FETs.

As used herein, “VDD” and “VSS” refer to the power supply voltages or the power supplies themselves. Also, as used herein, an expression indicating that sizes such as widths are identical, like the “same wiring width,” is to be understood as including a range of manufacturing variations.

### (Configuration of Circuit Block)

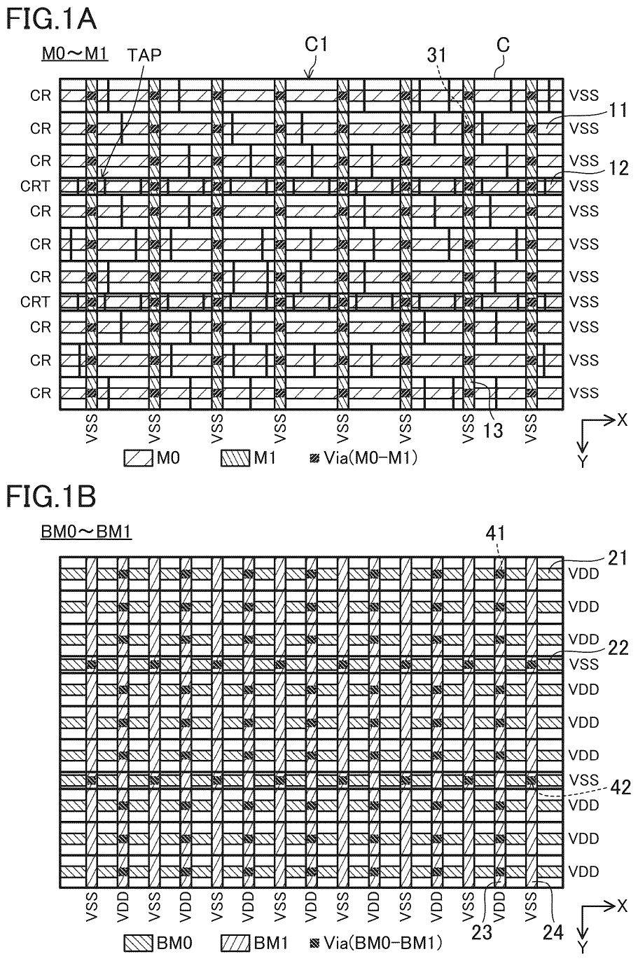

FIGS. 1A-3B are plan views showing a layout example of a circuit block included in a semiconductor integrated circuit device according to an embodiment. The block layout of FIGS. 1A-3B is made up by arranging standard cells. In FIGS. 1A-3B, only the cell frames of standard cells and power lines are illustrated, omitting the internal structures of the standard cells and interconnects between the standard cells.

In this embodiment, power lines are formed in an M0 layer, an M1 layer, an M2 layer, an M3 layer, an M4 layer, and an M5 layer that are interconnect layers provided on the upper side of a semiconductor chip in which transistors are formed. The M0 layer, the M1 layer, the M2 layer, the M3 layer, the M4 layer, and the M5 layer are located farther in this order from the transistors. Also, power lines are formed in a backside metal 0 (BM0) layer, a BM1 layer, a BM2 layer, a BM3 layer, a BM4 layer, and a BM5 layer that are interconnect layers provided on the back side of the semiconductor chip in which transistors are formed. The BM0 layer, the BM1 layer, the BM2 layer, the BM3 layer, the BM4 layer, and the BM5 layer are located farther in this order from the transistors.

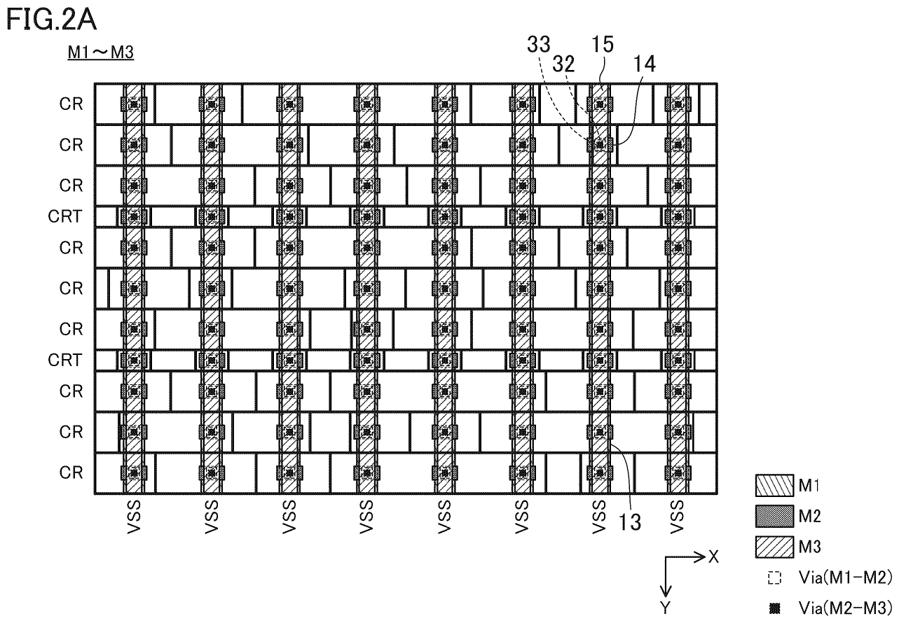

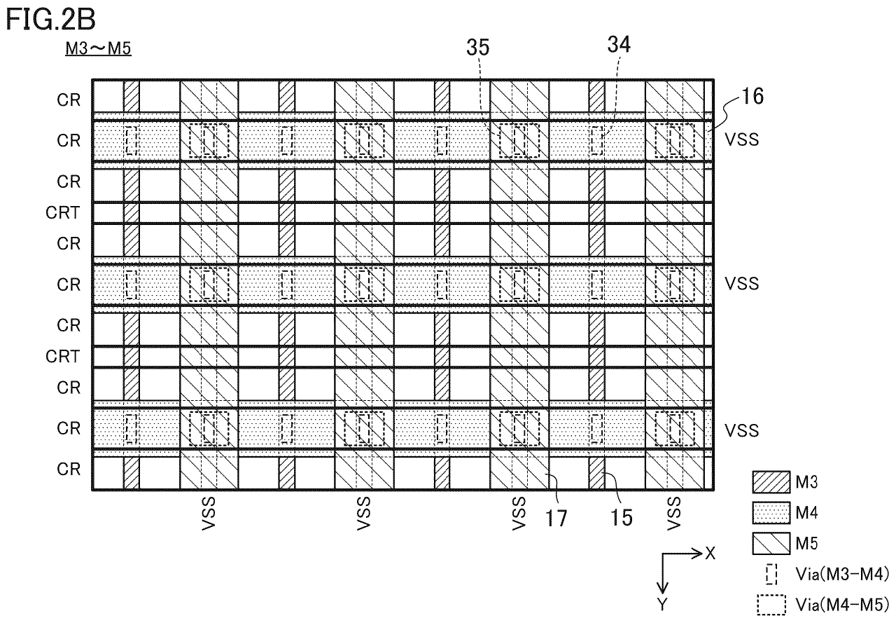

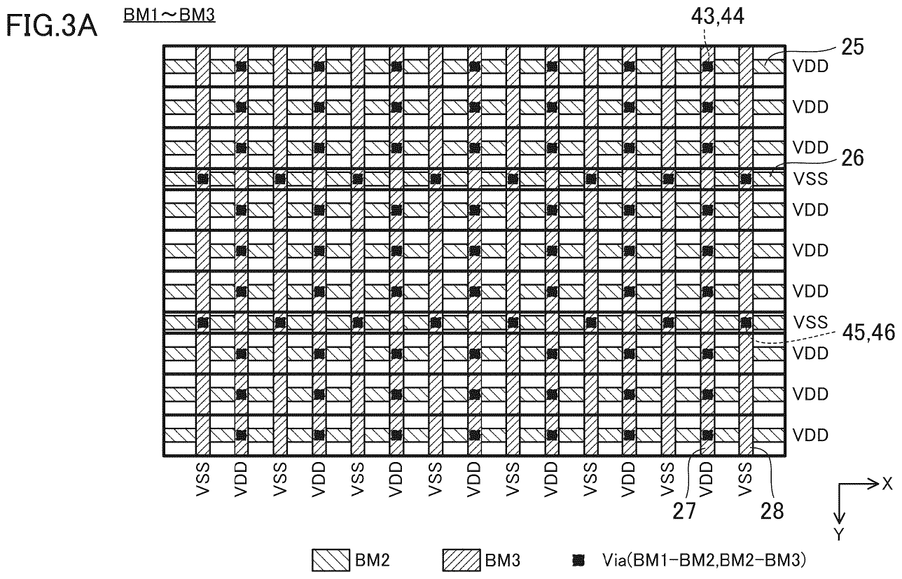

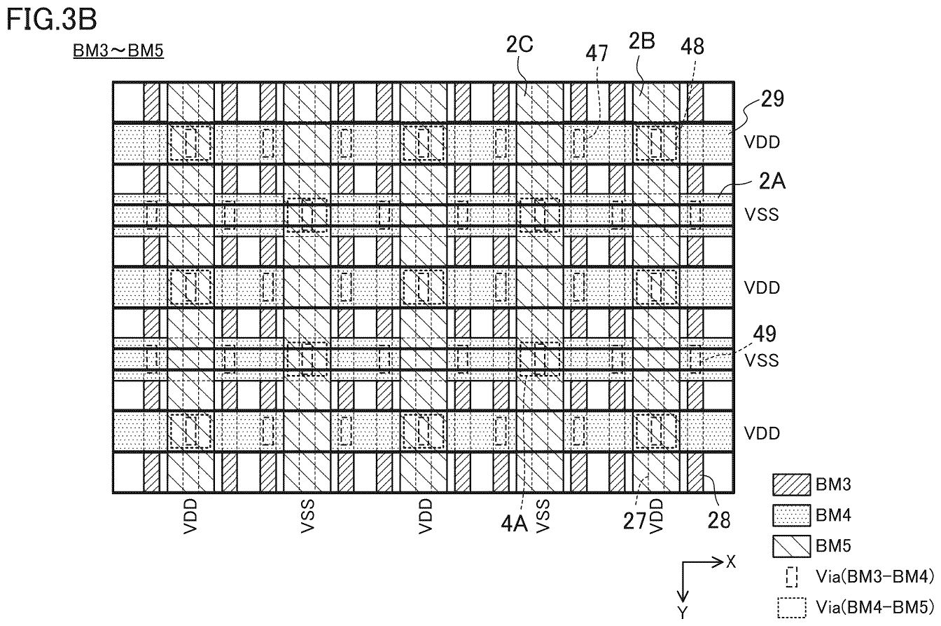

FIG. 1A shows the M0 layer and the M1 layer, and FIG. 1B shows the BM0 layer and the BM1 layer. FIG. 2A shows the M1 layer, the M2 layer, and the M3 layer, and FIG. 2B shows the M3 layer, the M4 layer, and the M5 layer. FIG. 3A shows the BM1 layer, the BM2 layer, and the BM3 layer, and FIG. 3B shows the BM3 layer, the BM4 layer, and the BM5 layer.

Note that FIGS. 1A, 2A, and 2B show configurations viewed from top, and the M1 layer, the M2 layer, the M3 layer, the M4 layer, and the M5 layer are stacked one upon another from the M0 layer upward in this order. On the other hand, FIGS. 1B, 3A, and 3B show configurations viewed from bottom, and the BM1 layer, the BM2 layer, the BM3 layer, the BM4 layer, and the BM5 layer are stacked one upon another from the BM0 layer upward in this order.

Note that, in the plan views such as FIGS. 1A, the horizontal direction in the figure is hereinafter referred to as an X direction (corresponding to the first direction), the vertical direction in the figure as a Y direction (corresponding to the second direction), and the direction perpendicular to the substrate plane as a Z direction. Also, hereinafter, the same components are denoted by the same reference characters, and description of such components may not be repeated.

In the layout of FIG. 1A, a plurality of cells C arranged in the X direction constitute a cell row CR, and a plurality of cell rows CR (nine rows in FIG. 1A) are arranged in the Y direction. The plurality of cells include cells having logical functions such as an inverter, a NAND gate, and a NOR gate. Specific layouts of the cells will be described later.

Also, power tap rows CRT extending in the X direction are placed between the cell rows CR. In FIG. 1A, power tap rows CRT are placed between the third and fourth cell rows CR from top in the figure, and between the third and fourth cell rows CR from bottom in the figure. Power tap cells TAP are formed in each power tap row CRT. The power tap cells TAP connect VSS lines on the upper side of the semiconductor chip and VSS lines on the back side of the semiconductor chip. The height (size in the Y direction) of the power tap rows CRT is smaller than the height of the cell rows CR. The detailed layout of the power tap cells will be described later. Note that, as will be described later, in the power tap rows CRT, power taps can also be provided without use of cells.

As shown in FIG. 1A, on the upper side of the semiconductor chip, power lines 11 and 12 extending in the X direction are formed in the M0 layer. The power lines 11 and 12 supply VSS. The power lines 11 overlap the cell rows CR in planar view, and the power lines 12 overlap the power tap rows CRT in planar view. In the M1 layer, power lines 13 extending in the Y direction are formed. The power lines 13 supply VSS. The power lines 11 and 12 in the M0 layer and the power lines 13 in the M1 layer are mutually connected through vias 31 formed at the intersections of these lines in planar view. In this way, a mesh of VSS power lines is formed.

As shown in FIG. 1B, on the back side of the semiconductor chip, power lines 21 and 22 extending in the X direction are formed in the BM0 layer. The power lines 21 supply VDD and the power lines 22 supply VSS. The power lines 21 overlap the cell rows CR in planar view, and the power lines 22 overlap the power tap rows CRT in planar view.

In the BM1 layer, power lines 23 and 24 extending in the Y direction are formed. The power lines 23 supply VDD and the power lines 24 supply VSS. The power lines 21 in the BM0 layer and the power lines 23 in the BM1 layer are mutually connected through vias 41 formed at the intersections of these lines in planar view. In this way, a mesh of VDD power lines is formed. The power lines 22 in the BM0 layer and the power lines 24 in the BM1 layer are mutually connected through vias 42 formed at the intersections of these lines in planar view. In this way, a mesh of VSS power lines is formed.

The cells C in the cell rows CR receive supply of VDD from the power lines 21 formed in the BM0 layer and receive supply of VSS from the power lines 11 formed in the M0 layer. Note that the design data of each cell includes a VDD power line in the BM0 layer and a VSS power line in the M0 layer, and such cells are arranged in the X direction, whereby the power line 21 formed in the BM0 layer and the power line 11 formed in the M0 layer are formed continuously in the X direction.

The power lines 13 in the M1 layer and the power lines 23 and 24 in the BM1 layer are laid at the time of block layout design. In the configuration of FIGS. 1A and 1B, the power lines 13 in the M1 layer and the power lines 24 supplying VSS in the BM1 layer are placed at the same pitch in the X direction and at the same positions in the X direction. That is, the power lines 13 in the M1 layer and the VSS-supply power lines 24 in the BM1 layer overlap each other in planar view.

Also, in the BM1 layer, the VDD-supply power lines 23 and the VSS-supply power lines 24 are placed alternately in the X direction.

As shown in FIG. 1A, the cell rows CR include a cell C1 large in width (size in the X direction). The width of the cell C1 is larger than the wiring spacing of the power lines 13 in the M1 layer. In other words, the cell C1 overlaps two or more (three in the figure) power lines 13 in the M1 layer in planar view.

FIGS. 2A and 2B show a configuration example of power lines in layers above the M1 layer. As shown in FIG. 2A, in the M2 layer, short power lines 14 are placed at the same positions as the power lines 11 and 12 in the M0 layer in the Y direction. The power lines 14 are formed at and around the same positions as the power lines 13 in the M1 direction in the X direction. The width of the power lines 14 may be the same as, or different from, the width of the power lines 11 and 12 in the M0 layer.

In the M3 layer, power lines 15 extending in the Y direction are placed. The power lines are formed at the same positions as the power lines 13 in the M1 layer in the X direction. The width of the power lines 15 may be the same as, or different from, the width of the power lines 13 in the M1 layer.

Vias 32 are formed between the power lines 14 in the M2 layer and the power lines 13 in the M1 layer. Also, vias 33 are formed between the power lines 15 in the M3 layer and the power lines 14 in the M2 layer. The vias 32 and 33 overlap the vias 31 formed between the power lines 11 and 12 in the M0 layer and the power lines 13 in the M1 layer in planar view. With this, since the resistance of the power lines is reduced, the power supply voltage drop can be reduced.

As shown in FIG. 2B, in the M4 layer, power lines 16 extending in the X direction are placed. The power lines 16 are larger in wiring pitch than the power lines 11 and 12 in the M0 layer. The power lines 16 overlap some of the power lines 11 in the M0 layer in planar view. Also, the power lines 16 is larger in width than the power lines 11 in the M0 layer.

In the M5 layer, power lines 17 extending in the Y direction are placed. The power lines 17 are larger in wiring pitch than the power lines 13 in the M1 layer. The power lines 17 overlap some of the power lines 13 in the M1 layer in planar view. Also, the power lines 17 is larger in width than the power lines 13 in the M1 layer.

Vias 34 are formed between the power lines 15 in the M3 layer and the power lines 16 in the M4 layer. Also, vias 35 are formed between the power lines 16 in the M4 layer and the power lines 17 in the M5 layer. The vias 34 overlap the vias 33 formed between the power lines 14 in the M2 layer and the power lines 15 in the M3 layer in planar view. Also, the vias 35 overlap some of the vias 34 in planar view. With this, since the resistance of the power lines is reduced, the power supply voltage drop can be reduced.

Note that more interconnect layers may be placed on the upper side of the semiconductor chip. Specifically, for example, interconnect layers having the same structures as the M2 layer and the M3 layer may be repeatedly stacked one upon another. Or, interconnect layers having the same structures as the M4 layer and the M5 layer may be repeatedly stacked one upon another. Alternatively, power lines further large in wiring width and wiring pitch may be formed in a layer above the M5 layer.

FIGS. 3A and 3B show a configuration example of power lines in layers below the BM1 layer. As shown in FIG. 3A, in the BM2 layer, power lines 25 and 26 extending in the X direction are placed. The power lines 25 supply VDD and the power lines 26 supply VSS. The power lines overlap the power lines 21 in the BM0 layer in planar view, and the power lines 26 overlap the power lines 22 in the BM0 layer in planar view. The width of the power lines 25 and 26 is the same as the width of the power lines 21 and 22 in the BM0 layer. Note however that the widths are not necessarily required to be the same.

In the BM3 layer, power lines 27 and 28 extending in the Y direction are placed. The power lines 27 supply VDD and the power lines 28 supply VSS. The power lines 27 are placed at the same positions as the power lines 23 in the BM1 layer in the X direction. The width of the power lines 27 is the same as the width of the power lines 23 in the BM1 layer. Note however that the widths are not necessarily required to be the same. The power lines 28 are placed at the same positions as the power lines 24 in the BM1 layer in the X direction. The width of the power lines 28 is the same as the width of the power lines 24 in the BM1 layer. Note however that the widths are not necessarily required to be the same.

As for VDD, the power lines 23 in the BM1 layer and the power lines 25 in the BM2 layer are mutually connected through vias 43 formed at the intersections of these lines in planar view. The power lines 25 in the BM2 layer and the power lines 27 in the BM3 layer are mutually connected through vias 44 formed at the intersections of these lines in planar view. The vias 43 and 44 overlap the vias 41 formed between the power lines 21 in the BM0 layer and the power lines 23 in the BM1 layer in planar view. With this, since the resistance of the power lines is reduced, the power supply voltage drop can be reduced.

As for VSS, the power lines 24 in the BM1 layer and the power lines 26 in the BM2 layer are mutually connected through vias 45 formed at the intersections of these lines in planar view. The power lines 26 in the BM2 layer and the power lines 28 in the BM3 layer are mutually connected through vias 46 formed at the intersections of these lines in planar view. The vias 45 and 46 overlap the vias 42 formed between the power lines 22 in the BM0 layer and the power lines 24 in the BM1 layer in planar view. With this, since the resistance of the power lines is reduced, the power supply voltage drop can be reduced.

As shown in FIG. 3B, in the BM4 layer, power lines 29 and 2A extending in the X direction are placed. The power lines 29 supply VDD and the power lines 2A supply VSS.

The power lines 29 are larger in wiring pitch than the power lines 25 in the BM2 layer. The power lines 29 overlap some of the power lines 25 in the BM2 layer in planar view, and are larger in width than the power lines 25 in the BM2 layer.

The power lines 2A overlap the power lines 26 in the BM2 layer in planar view, and are larger in width than the power lines 26 in the BM2 layer.

In the BM5 layer, power lines 2B and 2C extending in the Y direction are placed. The power lines 2B supply VDD and the power lines 2C supply VSS.

The power lines 2B are larger in wiring pitch than the power lines 27 in the BM3 layer. The power lines 2B overlap some of the power lines 27 in the BM3 layer in planar view, and are larger in width than the power lines 27 in the BM3 layer.

The power lines 2C are larger in wiring pitch than the power lines 28 in the BM3 layer. The power lines 2C overlap some of the power lines 28 in the BM3 layer in planar view, and are larger in width than the power lines 28 in the BM3 layer.

As for VDD, the power lines 27 in the BM3 layer and the power lines 29 in the BM4 layer are mutually connected through vias 47 formed at the intersections of these lines in planar view. The power lines 29 in the BM4 layer and the power lines 2B in the BM5 layer are mutually connected through vias 48 formed at the intersections of these lines in planar view. The vias 47 overlap the vias 41 formed between the power lines 21 in the BM0 layer and the power lines 23 in the BM1 layer in planar view. The vias 48 overlap the vias 47 in planar view. With this, since the resistance of the power lines is reduced, the power supply voltage drop can be reduced.

As for VSS, the power lines 28 in the BM3 layer and the power lines 2A in the BM4 layer are mutually connected through vias 49 formed at the intersections of these lines in planar view. The power lines 2A in the BM4 layer and the power lines 2C in the BM5 layer are mutually connected through vias 4A formed at the intersections of these lines in planar view. The vias 49 overlap the vias 42 formed between the power lines 22 in the BM0 layer and the power lines 24 in the BM1 layer in planar view. The vias 4A overlap the vias 49 in planar view. With this, since the resistance of the power lines is reduced, the power supply voltage drop can be reduced.

Note that more interconnect layers may be placed on the back side of the semiconductor chip. Specifically, for example, a plurality of interconnect layers having the same structures as the BM2 layer and the BM3 layer may be repeatedly stacked one upon another. Or, a plurality of interconnect layers having the same structures as the BM4 layer and the BM5 layer may be repeatedly stacked one upon another. Alternatively, power lines further large in wiring width and wiring pitch may be formed in a layer below the BM5 layer.

### Other Configuration Example

All or some of the power lines formed on the back side of transistors may be formed using a semiconductor chip other than the semiconductor chip in which the transistors are formed.

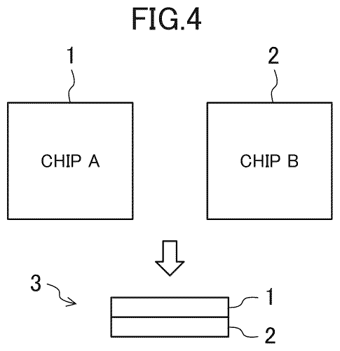

FIG. 4 shows another configuration example of the semiconductor integrated circuit device according to the embodiment. A semiconductor integrated circuit device 3 shown in FIG. 4 is constituted by a first semiconductor chip 1 (chip A) and a second semiconductor chip 2 (chip B) stacked one upon the other. In the chip A, standard cells having transistors are placed. In the chip B, power lines are formed in interconnect layers provided on the surface. The chip B is bonded to the back of the chip A using bumps and the like.

The power lines in the BM0 layer to the BM5 layers described above may be formed in the chip B. Alternatively, power lines in some of the BM0 layer to the BM5 layer, e.g., the power lines in the BM1 layer to BM5 layer may be formed in the chip B. In this case, the power lines in the BM0 layer are to be formed on the back side of the chip A.

### (Layout of Cells)

As examples of the cells C constituting the cell rows CR, layout structure examples of an inverter cell, a 2-input NAND cell, and a 2-input NOR cell will be described.

### <Inverter Cell>

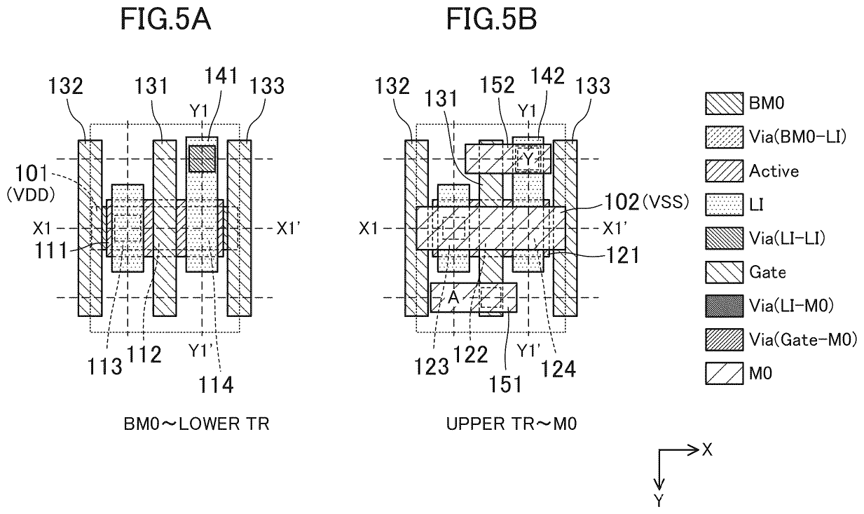

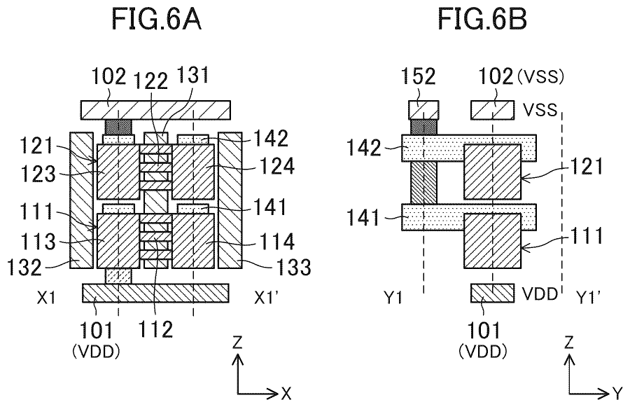

FIGS. 5A-5B and 6A-6B are views showing an example of the layout structure of an inverter cell, where FIGS. 5A and 5B are plan views, FIG. 6A is a cross-sectional view taken horizontally in planar view, and FIG. 6B is a cross-sectional view taken vertically in planar view. Specifically, FIG. 5A shows a lower part that is a part including a lower transistor (p-type nanosheet FET in the illustrated example) formed on the side closer to the substrate, and FIG. 5B shows an upper part that is a part including an upper transistor (n-type nanosheet FET in the illustrated example) formed on the side farther from the substrate. FIG. 6A shows a cross section taken along line X1-X1′ in FIGS. 5A and 5B, and FIG. 6B shows a cross section taken along line Y1-Y1′ in FIGS. 5A and 5B.

As shown in FIG. 5A, inside the cell, a power line 101 extending in the X direction is placed in the BM0 layer. The power line 101 supplies VDD. The power line 101 is shared with the other cells in the cell row including the inverter cell, forming the power line 21 extending in the X direction shown in FIG. 1B.

As shown in FIG. 5B, inside the cell, a power line 102 extending in the X direction is placed in the M0 layer. The power line 102 supplies VSS. The power line 102 is shared with the other cells in the cell row including the inverter cell, forming the power line 11 extending in the X direction shown in FIG. 1A.

An active region 111 forming the channel, source, and drain of the p-type nanosheet FET is formed above the power line 101. The active region 111 includes a nanosheet 112 that is to be the channel of the p-type nanosheet FET. In the active region 111, a portion 113 that is to be the source of the p-type nanosheet FET is connected to the power line 101 through a via.

An active region 121 forming the channel, source, and drain of the n-type nanosheet FET is formed above the active region 111 and below the power line 102. The active region 121 includes a nanosheet 122 that is to be the channel of the n-type nanosheet FET. In the active region 121, a portion 123 that is to be the source of the n-type nanosheet FET is connected to the power line 102 through a via and a local interconnect.

Note that, in the active regions, portions that are to be the sources and drains on both sides of the nanosheets are formed by epitaxial growth from the nanosheets.

A gate interconnect 131 extends in the Y direction in roughly the center of the cell in the X direction, and also extends in the Z direction from the lower part over to the upper part of the cell. The gate interconnect 131 surrounds the peripheries of the nanosheets 112 and 122 in the Y direction and the Z direction through gate insulating films (not shown). The gate interconnect 131 is to be the gates of the p-type nanosheet FET and the n-type nanosheet FET. Also, dummy gate interconnects 132 and 133 are formed on both sides of the cell frame in the X direction.

In the lower part, a local interconnect 141 extending in the Y direction is formed. The local interconnect 141 is connected to a portion 114 that is to be the drain of the p-type nanosheet FET in the active region 111. In the upper part, a local interconnect 142 extending in the Y direction is formed. The local interconnect 142 is connected to a portion 124 that is to be the drain of the n-type nanosheet FET in the active region 121. The local interconnects 141 and 142 are mutually connected through a via.

In the M0 layer, signal lines 151 and 152 extending in the X direction are formed. The signal line 151 corresponds to an input A of the inverter circuit, and the signal line 152 corresponds to an output Y of the inverter circuit. The signal line 151 is connected to the gate interconnect 131 through a via, and the signal line 152 is connected to the local interconnect 142 through a via.

### <2-Input NAND Cell>

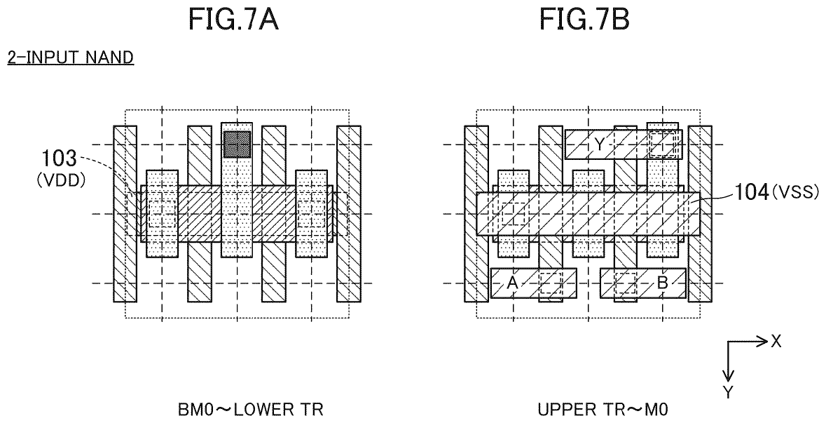

FIGS. 7A-7B are plan views showing an example of the layout structure of a 2-input NAND cell, where FIG. 7A shows a lower part and FIG. 7B shows an upper part.

As shown in FIG. 7A, inside the cell, a power line 103 extending in the X direction is placed in the BM0 layer. The power line 103 supplies VDD. The power line 103 is shared with the other cells in the cell row including the 2-input NAND cell, forming the power line 21 extending in the X direction shown in FIG. 1B.

As shown in FIG. 7B, inside the cell, a power line 104 extending in the X direction is placed in the M0 layer. The power line 104 supplies VSS. The power line 104 is shared with the other cells in the cell row including the 2-input NAND cell, forming the power line 11 extending in the X direction shown in FIG. 1A.

The other part of the layout structure can be easily inferred by analogy from the above description on the inverter cell, and therefore detailed description is omitted here.

### <2-Input NOR Cell>

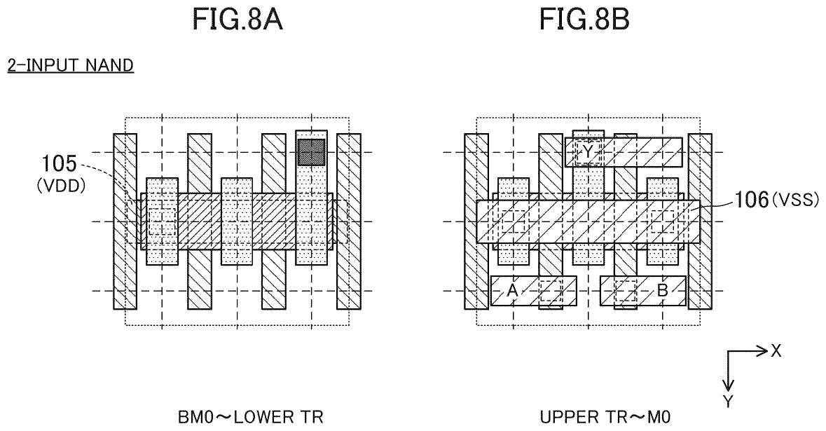

FIGS. 8A-8B are plan views showing an example of the layout structure of a 2-input NOR cell, where FIG. 8A shows a lower part and FIG. 8B shows an upper part.

As shown in FIG. 8A, inside the cell, a power line 105 extending in the X direction is placed in the BM0 layer. The power line 105 supplies VDD. The power line 105 is shared with the other cells in the cell row including the 2-input NOR cell, forming the power line 21 extending in the X direction shown in FIG. 1B.

As shown in FIG. 8B, inside the cell, a power line 106 extending in the X direction is placed in the M0 layer. The power line 106 supplies VSS. The power line 106 is shared with the other cells in the cell row including the 2-input NOR cell, forming the power line 11 extending in the X direction shown in FIG. 1A.

The other part of the layout structure can be easily inferred by analogy from the above description on the inverter cell, and therefore detailed description is omitted here.

Note that layout structures of cells other than the inverter cell, the 2-input NAND cell, and the 2-input NOR cell can be easily inferred by analogy from the above description, and therefore detailed description is omitted here. For example, the cell C1 large in width shown in FIG. 1A also includes, like the inverter cell, a p-type nanosheet FET as the lower transistor, an n-type nanosheet FET as the upper transistor, a power line supplying VDD formed in the BM0 layer, and a power line supplying VSS formed in the M0 layer.

### <Power Tap Cell>

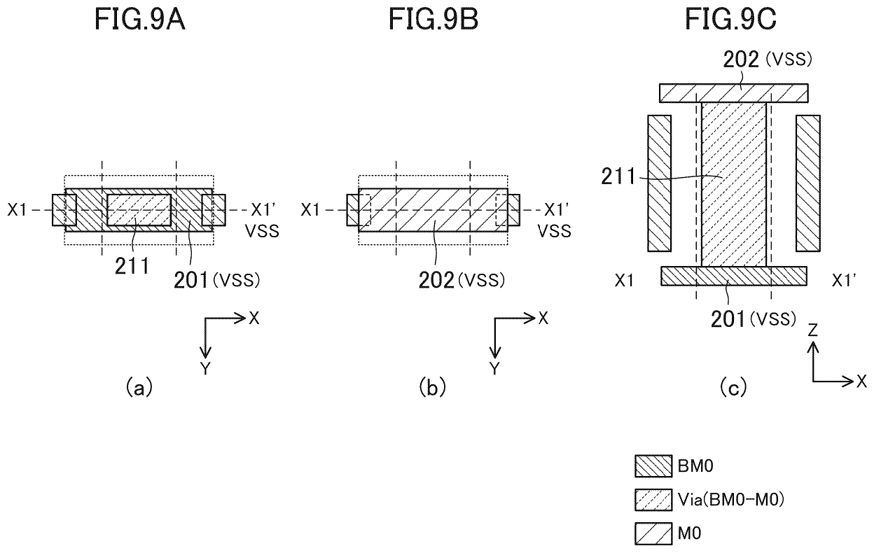

FIGS. 9A-9C are views showing an example of the layout structure of a power tap cell TAP placed in the power tap row CRT, where FIGS. 9A and 9B are plan views and FIG. 9C is a cross-sectional view. FIG. 9A shows a lower part, FIG. 9B shows an upper part, and FIG. 9C shows a cross section taken along line X1-X1′ in FIGS. 9A and 9B.

As shown in FIG. 9A, inside the cell, a power line 201 extending in the X direction is placed in the BM0 layer. The power line 201 supplies VSS. Since such power tap cells are arranged in the X direction, the power line 201 is shared with the other power tap cells, forming the power line 22 extending in the X direction shown in FIG. 1B.

As shown in FIG. 9B, inside the cell, a power line 202 extending in the X direction is placed in the M0 layer. The power line 202 supplies VSS. Since such power tap cells are arranged in the X direction, the power line 202 is shared with the other power tap cells, forming the power line 12 extending in the X direction shown in FIG. 1A.

The power line 201 in the BM0 layer and the power line 202 in the M0 layer are mutually connected through a via 211 that is an example of the connection structure. The connection structure for connecting the power line 201 and the power line 202 is not limited to the single via 211. For example, the connection structure for connecting the power line 201 and the power line 202 may be constituted by interconnects in a plurality of layers and vias formed to overlap one another in planar view.

The power tap cell shown in FIGS. 9A-9C is smaller in height (size in the Y direction) than the inverter cell and the like described above. The configuration is however not limited to this.

By preparing power tap cells as shown in FIGS. 9A-9C in advance and arranging the power tap cells in the X direction, it is possible to constitute the power tap row CRT described above and connect the VSS lines on the upper side and the VSS lines on the back side.

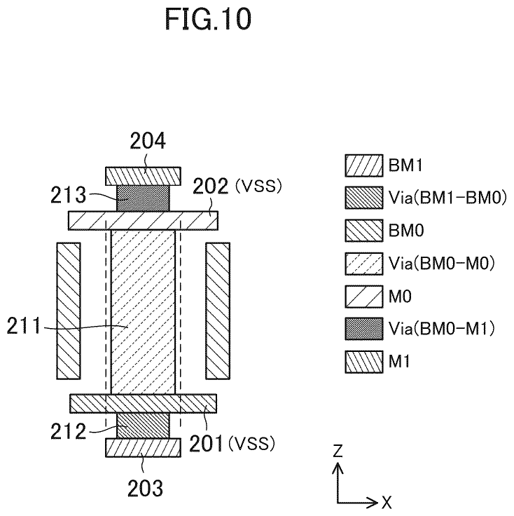

FIG. 10 is a cross-sectional view showing a configuration of the neighborhood of the power tap cell. In the structure of FIG. 10, a power line 203 in the BM1 layer and a power line 204 in the M1 layer are shown in addition to the cross-sectional structure of FIG. 9C. The power line 203 in the BM1 layer is connected to the power line 201 in the BM0 layer through a via 212. The power line 204 in the M1 layer is connected to the power line 202 in the M0 layer through a via 213.

The vias 212 and 213 are placed at positions overlapping the via 211 of the power tap cell in the X direction. Therefore, since the route from the power line in the M1 layer down to the power line in the BM1 layer can be formed linearly, the resistance of the power lines can be reduced, and thus the power supply voltage drop can be reduced.

Note that, in this embodiment, the power tap row CRT is formed by arranging the power tap cells TAP in line. Instead of this, the power tap row CRT may be formed by placing necessary power lines, such as the power line 12 shown in FIG. 1A and the power line 22 shown in FIG. 1B, for example, and placing a connection structure for connecting these power lines, such as vias. That is, the power taps included in the power tap row CRT are not limited to those formed by cells.

According to this embodiment, in the semiconductor integrated circuit device, the power tap row CRT including a plurality of power taps is provided adjacently to a plurality of cell rows each including standard cells C arranged in the X direction. Each standard cell C includes the p-type nanosheet FET and the n-type nanosheet FET overlapping each other in planar view, the power line 21 supplying VDD formed in the BM0 layer, and the power line 11 supplying VSS formed in the M0 layer. Each power tap includes the power line 22 supplying VSS formed in the BM0 layer, the power line 12 supplying VSS formed in the M0 layer, and the via 211 connecting the power lines 12 and 22. In this way, since the power tap row CRT is provided separately from the cell rows CR, it is unnecessary to place a power tap cell in the cell rows CR. Also, the semiconductor integrated circuit device includes a plurality of power lines 24 supplying VSS formed in the BM1 layer, and the width, i.e., the size in the X direction of the cell C1 is larger than the pitch of placement of the power lines 24. That is, in the cell rows CR, the degree of freedom of placement of cells large in circuit scale, like the cell C1, enhances. This makes the design of the semiconductor integrated circuit device easy, and therefore the performance of the semiconductor integrated circuit device can be improved.

Also, the height, i.e., the size in the Y direction of the power tap row CRT is smaller than the height of the cell row CR. It is therefore possible to hold down increase in the area of the semiconductor integrated circuit device.

While power lines supplying VDD are formed in the BM0 layer and power lines supplying VSS are formed in the M0 layer in the above embodiment, the power supplies VDD and VSS may be reversed with each other. That is, power lines supplying VSS may be formed in the BM0 layer and power lines supplying VDD may be formed in the M0 layer. In this case, in the configuration of the embodiment described above, VDD and VSS may be entirely changed with each other, and, as the conductivity types of the nanosheet FETs in each cell, the n-type may be used on the lower side and the p-type on the upper side.

While the nanosheet is illustrated to have a structure of three sheets lying one above another and having a rectangular cross-sectional shape in the embodiment descried above, the number of sheets and cross-sectional shape of the sheet structure of the nanosheet are not limited to these.

Also, while the transistors are nanosheet FETs in the embodiment described above, the configuration is not limited to this. For example, fin FETs or other types of transistors may be used.

According to the present disclosure, in a semiconductor integrated circuit device having power taps, the degree of freedom of placement of cells large in circuit scale can be enhanced. The present disclosure is therefore useful for cost reduction and performance improvement of the semiconductor integrated circuit device, for example.

1. A semiconductor integrated circuit device, comprising:
a plurality of cell rows each including a plurality of standard cells arranged in a first direction, the cell rows being arranged adjacently in a second direction perpendicular to the first direction; and
a power tap row including a plurality of power taps arranged in the first direction, the power tap row being adjacent to the plurality of cell rows in the second direction, wherein
the plurality of cell rows include a first standard cell,
the first standard cell includes
a first transistor of a first conductivity type,
a second transistor of a second conductivity type formed above the first transistor in a depth direction and overlapping the first transistor in planar view,
a first power line formed in a first interconnect layer located on a back side of the first and second transistors, extending in the first direction, and supplying a first power supply voltage to the first transistor, and
a second power line formed in a second interconnect layer located on an upper side of the first and second transistors, extending in the first direction, and supplying a second power supply voltage to the second transistor,
the power tap includes
a third power line formed in the first interconnect layer, extending in the first direction, and supplying the second power supply voltage,
a fourth power line formed in the second interconnect layer, extending in the first direction, overlapping the third power line in planar view, and supplying the second power supply voltage, and
a connection structure for connecting the third power line and the fourth power line,
the semiconductor integrated circuit device further comprises
a plurality of fifth power lines formed in a third interconnect layer located below the first interconnect layer, extending in the second direction, and supplying the second power supply voltage,
the plurality of fifth power lines are arranged at a first pitch in the first direction, and
the size of the first standard cell in the first direction is larger than the first pitch.

2. The semiconductor integrated circuit device of claim 1, wherein
the connection structure of the power tap is constituted by a via that overlaps the third and fourth power lines, is in contact with the third power line, and is in contact with the fourth power line.

3. The semiconductor integrated circuit device of claim 1, wherein
the size of the power tap in the second direction is smaller than the size of the cell row in the second direction.

4. The semiconductor integrated circuit device of claim 1, comprising:
a first semiconductor chip in which the first and second transistors are formed; and
a second semiconductor chip bonded to a back of the first semiconductor chip, wherein
the third interconnect layer in which the plurality of fifth power lines are formed is provided in the second semiconductor chip.
